(19) United States
(12) Patent Application Publication
(10) Pub. No.: US 2022/0403550 A1
(43) Pub. Date: Dec. 22, 2022

(54) SILICON CARBIDE SUBSTRATE AND METHOD FOR MANUFACTURING SILICON CARBIDE SUBSTRATE

(71) Applicant: SUMITOMO ELECTRIC INDUSTRIES, LTD., Osaka (JP)

(72) Inventors: Kyoko OKITA, Osaka (JP); Tsubasa HONKE, Osaka (JP); Shunsaku UETA, Osaka (JP)

(21) Appl. No.: 17/780,355

(22) PCT Filed: Nov. 12, 2020
(86) PCT No.: PCT/JP2020/042189

§ 371 Date: May 26, 2022

(30) Foreign Application Priority Data
Dec. 2, 2019 (JP) 2019-218125

(51) Int. Cl. C30B 25/18; H01L 21/02; C30B 29/36; C30B 33/10

(52) U.S. Cl. CPC C30B 25/186; H01L 21/02013; H01L 21/02019; H01L 21/02052; C30B 29/36; C30B 33/10; H01L 29/1608

(57) ABSTRACT

A ratio obtained by dividing a number of pits by a number of screw dislocations is equal to or smaller than 1%. The first main surface has a surface roughness equal to or smaller than 0.15 nm. An absolute value of a difference between the first wave number and the second wave number is equal to or smaller than 0.2 cm⁻¹, and an absolute value of a difference between the first full width at half maximum and the second full width at half maximum is equal to or smaller than 0.25 cm⁻¹.

### TECHNICAL FIELD

The present disclosure relates to a silicon carbide substrate and a method for manufacturing a silicon carbide substrate. The present application claims priority based on Japanese Patent Application No. 2019-218125 filed on Dec. 2, 2019. The entire contents described in Japanese Patent Application No. 2019-218125 are incorporated herein by reference.

### BACKGROUND ART

Japanese Patent Laying-Open No. 2014-210690 (PTL 1) describes that chemical mechanical polishing is performed on a silicon carbide single crystal substrate.

### CITATION LIST

### Patent Literature

PTL 1: Japanese Patent Laying-Open No. 2014-210690

### SUMMARY OF INVENTION

A silicon carbide substrate according to the present disclosure includes a first main surface and a second main surface opposite to the first main surface. The silicon carbide substrate includes: screw dislocations; and pits having a maximum diameter equal to or greater than 1 μm and equal to or smaller than 10 μm in a direction parallel to the first main surface. When the screw dislocations and the pits are observed on the first main surface, a ratio obtained by dividing a number of the pits by a number of the screw dislocations is equal to or smaller than 1%. The first main surface has a surface roughness equal to or smaller than 0.15 nm. Assuming that in a first square region including the screw dislocations and having a side length of 200 μm, an average value of wave numbers indicating peaks corresponding to a folding mode of a longitudinal optical branch of a Raman spectrum of silicon carbide is set as a first wave number, that in a second square region including no screw dislocation and having a side length of 200 μm, an average value of wave numbers indicating peaks corresponding to a folding mode of a longitudinal optical branch of a Raman spectrum of silicon carbide is set as a second wave number, that in the first square region, an average value of full widths at half maximum of the peaks corresponding to the folding mode of the longitudinal optical branch of the Raman spectrum of silicon carbide is set as a first full width at half maximum, and that in the second square region, an average value of full widths at half maximum of the peaks corresponding to the folding mode of the longitudinal optical branch of the Raman spectrum of silicon carbide is set as a second full width at half maximum, an absolute value of a difference between the first wave number and the second wave number is equal to or smaller than 0.2 cm⁻¹, and an absolute value of a difference between the first full width at half maximum and the second full width at half maximum is equal to or smaller than 0.25 cm⁻¹.

A method for manufacturing a silicon carbide substrate according to the present disclosure includes the following steps. A silicon carbide single crystal substrate having a first main surface and a second main surface on an opposite side of the first main surface is prepared. Mechanical polishing is performed to the silicon carbide single crystal substrate on the first main surface. Etching is performed to the silicon carbide single crystal substrate after the mechanical polishing to the silicon carbide single crystal substrate. Chemical mechanical polishing is performed to the silicon carbide single crystal substrate using abrasive grains and an oxidant on the first main surface after the etching to the silicon carbide single crystal substrate. In the mechanical polishing to the silicon carbide single crystal substrate, a damage layer is provided on the first main surface. In the etching to the silicon carbide single crystal substrate, the damage layer is removed. In the chemical mechanical polishing to the silicon carbide single crystal substrate, when, taking a surface roughness of the first main surface as a vertical axis and a concentration of the oxidant as a horizontal axis, a relationship between the surface roughness and the concentration of the oxidant is approximated by a first quadratic curve, the concentration of the oxidant is within a range in which the surface roughness is equal to or smaller by 1.5 times than a local minimum value of the first quadratic curve, and a polishing speed of the silicon carbide single crystal substrate is equal to or higher than 0.2 μm/hour.

### BRIEF DESCRIPTION OF DRAWINGS

FIG. 1 is a schematic plan view illustrating a configuration of a silicon carbide substrate according to the present embodiment.

FIG. 2 is a schematic cross-sectional view taken along line II-II in FIG. 1.

FIG. 3 is a schematic enlarged view of a region III in FIG. 2.

FIG. 4 is a schematic enlarged view of a region IV in FIG. 1.

FIG. 5 is a schematic view illustrating a configuration of a Raman spectrometer.

FIG. 6 is a schematic view illustrating measurement points of a Raman spectrum in a first square region.

FIG. 7 is a schematic view illustrating measurement points of a Raman spectrum in a second square region.

FIG. 8 is a schematic view illustrating one example of a Raman spectrum of a silicon carbide substrate.

FIG. 9 is a schematic view illustrating the Raman spectrum measured in the first square region and the Raman spectrum measured in the second square region.

FIG. 10 is a flow chart schematically illustrating a method for manufacturing a silicon carbide substrate according to the present embodiment.

FIG. 11 is a partial schematic cross-sectional view illustrating a first step of the method for manufacturing a silicon carbide substrate according to the present embodiment.

FIG. 12 is a partial schematic cross-sectional view illustrating a second step of the method for manufacturing a silicon carbide substrate according to the present embodiment.

FIG. 13 is a partial schematic cross-sectional view illustrating a third step of the method for manufacturing a silicon carbide substrate according to the present embodiment.

FIG. 14 is a chart showing a relationship between a polishing speed and an oxidant concentration, and a relationship between a surface roughness and the oxidant concentration.

FIG. 15 is a chart showing a relationship between the polishing speed and an abrasive grain diameter, and a relationship between the surface roughness and the abrasive grain diameter.

FIG. 16 is a partial schematic cross-sectional view illustrating a configuration of a silicon carbide substrate according to the present embodiment.

FIG. 17 is a schematic cross-sectional view illustrating a configuration of a silicon carbide single crystal substrate after CMP in a case where chemical elements are dominant.

FIG. 18 is a schematic cross-sectional view illustrating a configuration of a silicon carbide single crystal substrate after CMP in a case where mechanical elements are dominant.

FIG. 19 is a schematic cross-sectional view illustrating a configuration of a silicon carbide substrate after hydrogen etching is performed to a silicon carbide substrate after CMP in a case where mechanical elements are dominant.

FIG. 20 is a schematic cross-sectional view illustrating a configuration of a silicon carbide substrate after hydrogen etching is performed to a silicon carbide substrate after CMP in a case where mechanical elements and chemical elements are balanced.

### DETAILED DESCRIPTION

### Problem to be Solved by the Present Disclosure

An object of the present disclosure is to suppress formation of pits after epitaxial growth.

### Advantageous Effect of the Present Disclosure

According to the present disclosure, it is possible to provide a silicon carbide substrate capable of suppressing formation of pits after epitaxial growth, and a method for manufacturing a silicon carbide substrate.

### Description of Embodiments

(1) A silicon carbide substrate 10 according to the present disclosure includes a first main surface 1 and a second main surface 2 opposite to first main surface 1. Silicon carbide substrate 10 includes: screw dislocations 13; and pits 11 having a maximum diameter equal to or greater than 1 μm and equal to or smaller than 10 μm in a direction parallel to first main surface 1. When screw dislocations 13 and pits 11 are observed on first main surface 1, a ratio obtained by dividing a number of pits 11 by a number of screw dislocations 13 is equal to or smaller than 1%. First main surface 1 has a surface roughness equal to or smaller than 0.15 nm. Assuming that in a first square region 14 including screw dislocations 13 and having a side length of 200 μm, an average value of wave numbers indicating peaks corresponding to a folding mode of a longitudinal optical branch of a Raman spectrum of silicon carbide is set as a first wave number, that in a second square region 15 including no screw dislocation 13 and having a side length of 200 μm, an average value of wave numbers indicating peaks corresponding to a folding mode of a longitudinal optical branch of a Raman spectrum of silicon carbide is set as a second wave number, that in first square region 14, an average value of full widths at half maximum of the peaks corresponding to the folding mode of the longitudinal optical branch of the Raman spectrum of silicon carbide is set as a first full width at half maximum, and that in second square region 15, an average value of full widths at half maximum of the peaks corresponding to the folding mode of the longitudinal optical branch of the Raman spectrum of silicon carbide is set as a second full width at half maximum, an absolute value of a difference between the first wave number and the second wave number is equal to or smaller than 0.2 cm⁻¹, and an absolute value of a difference between the first full width at half maximum and the second full width at half maximum is equal to or smaller than 0.25 cm⁻¹.

(2) According to silicon carbide substrate 10 described in (1), the ratio obtained by dividing the number of pits 11 by the number of screw dislocations 13 may be equal to or smaller than 0.5%.

(3) According to silicon carbide substrate 10 described in (1), the ratio obtained by dividing the number of pits 11 by the number of screw dislocations 13 may be equal to or smaller than 0.4%.

(4) According to silicon carbide substrate 10 described in any of (1) to (3), the surface roughness of first main surface 1 may be equal to or smaller than 0.1 nm.

(5) According to silicon carbide substrate 10 described in any of (1) to (4), a diameter of first main surface 1 may be equal to or greater than 150 mm.

(6) According to silicon carbide substrate 10 described in any of (1) to (5), a surface density of screw dislocations 13 on first main surface 1 may be equal to or greater than 100 cm⁻² and equal to or smaller than 5000 cm⁻².

(7) A method for manufacturing silicon carbide substrate 10 according to the present disclosure includes the following steps. A silicon carbide single crystal substrate 100 having first main surface 1 and second main surface 2 on an opposite side of first main surface 1 is prepared. Mechanical polishing is performed to silicon carbide single crystal substrate 100 on first main surface 1. Etching is performed to silicon carbide single crystal substrate 100 after the mechanical polishing to silicon carbide single crystal substrate 100. Chemical mechanical polishing is performed to silicon carbide single crystal substrate 100 using abrasive grains and an oxidant on first main surface 1 after the etching to silicon carbide single crystal substrate 100. In the mechanical polishing to silicon carbide single crystal substrate 100, a damage layer 23 is provided on first main surface 1. In the etching to silicon carbide single crystal substrate 100, damage layer 23 is removed. In the chemical mechanical polishing to silicon carbide single crystal substrate 100, when, taking a surface roughness of first main surface 1 as a vertical axis and a concentration of the oxidant as a horizontal axis, a relationship between the surface roughness and the concentration of the oxidant is approximated by a first quadratic curve, the concentration of the oxidant is within a range in which the surface roughness is equal to or smaller by 1.5 times than a local minimum value of the first quadratic curve, and a polishing speed of silicon carbide single crystal substrate 100 is equal to or higher than 0.2 μm/hour.

(8) According to the method for manufacturing silicon carbide substrate 10 described in (7), in the chemical mechanical polishing to silicon carbide single crystal substrate 100, when, taking the surface roughness of first main surface 1 as the vertical axis and the diameter of the abrasive grains as the horizontal axis, a relationship between the surface roughness and the diameter of the abrasive grains is approximated by a second quadratic curve, the diameter of the abrasive grains is within a range in which the surface roughness is equal to or smaller by 1.5 times than a local minimum value of the second quadratic curve.

(9) According to the method for manufacturing silicon carbide substrate 10 described in (7) or (8), the etching to silicon carbide single crystal substrate 100 may be performed under a temperature equal to or lower than 400° C.

(10) According to the method for manufacturing silicon carbide substrate 10 described in any of (7) to (9), the local minimum value of the first quadratic curve may be equal to or smaller than 0.15 nm.

(11) According to the method for manufacturing silicon carbide substrate 10 described in any of (7) to (10), the abrasive grains may be colloidal silica.

(12) According to the method for manufacturing silicon carbide substrate 10 described in any of (7) to (11), the etching to silicon carbide single crystal substrate 100 may be performed by causing damage layer 23 to be immersed in a solution.

(13) According to the method for manufacturing silicon carbide substrate 10 described in (12), the solution may contain potassium permanganate and potassium hydroxide.

### Details of Embodiments

Hereinafter, embodiments of the present disclosure will be described with reference to the drawings. In the following drawings, the same or corresponding parts are denoted by the same reference numerals, and description thereof will not be repeated. In crystallographic descriptions in the present specification, an individual orientation is indicated by [ ], a group orientation is indicated by < >, an individual plane is indicated by ( ) and a group plane is indicated by { }. While crystallographically a negative index is expressed by attaching “-” (bar) above a number, a negative index in the present specification is expressed by a negative sign attached before a number.

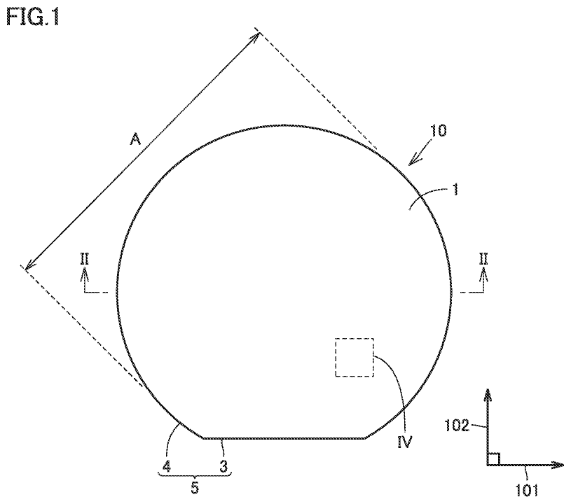

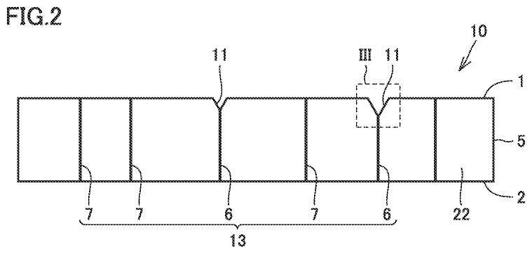

First, a configuration of a silicon carbide substrate according to the present embodiment will be described. FIG. 1 is a schematic plan view illustrating the configuration of the silicon carbide substrate according to the present embodiment. FIG. 2 is a schematic cross-sectional view taken along line II-II in FIG. 1.

As illustrated in FIGS. 1 and 2, a silicon carbide substrate 10 according to the present embodiment mainly includes a first main surface 1, a second main surface 2, and an outer peripheral surface 5. As illustrated in FIG. 2, second main surface 2 is on an opposite side of first main surface 1. Silicon carbide substrate 10 is configured by 4H polytype silicon carbide. Silicon carbide substrate 10 contains n-type impurity, such as nitrogen (N), for example. A conductivity type of silicon carbide substrate 10 is n-type, for example. A concentration of n-type impurity in silicon carbide substrate 10 is equal to or greater than 1×10¹⁷ cm⁻³ and equal to or smaller than 1×10²⁰ cm⁻³, for example.

As illustrated in FIG. 1, a maximum diameter A of first main surface 1 is, for example, equal to or greater than 150 mm (equal to or greater than 6 inches). Maximum diameter A of first main surface 1 may be equal to or greater than 200 mm (8 inches), for example. As used herein, 2 inches mean 50 mm or 50.8 mm (25.4 mm/inch×2 inches). 3 inches mean 75 mm or 76.2 mm (25.4 mm/inch×3 inches). 4 inches mean 100 mm or 101.6 mm (25.4 mm/inch×4 inches). 5 inches mean 125 mm or 127.0 mm (25.4 mm/inch×5 inches). 6 inches mean 150 mm or 152.4 mm (25.4 mm/inch×6 inches). 8 inches mean 200 mm or 203.2 mm (25.4 mm/inch×8 inches).

First main surface 1 is a plane inclined at an off angle greater than 0° and equal to or smaller than 8° with respect to {0001} plane or {0001} plane, for example. The off angle may be equal to or greater than 1°, for example, or may be equal to or greater than 2°. The off angle may be equal to or smaller than 7°, or may be equal to or smaller than 6°. Specifically, first main surface 1 may be a plane inclined at an off angle greater than 0° and equal to or smaller than 8° with respect to (0001) plane or (0001) plane. First main surface 1 may be a plane inclined at an off angle greater than 0° and equal to or smaller than 8° with respect to (000-1) plane or (000-1) plane. An inclination orientation of first main surface 1 is <11-20> orientation, for example.

As illustrated in FIG. 1, outer peripheral surface 5 may include a first flat 3 and an arcuate portion 4, for example. First flat 3 extends along a first direction 101, for example. Arcuate portion 4 continues from first flat 3. Outer peripheral surface 5 may include a second flat (not shown) extending along a second direction 102. Second direction 102 is <1-100> direction, for example. First direction 101 is a direction that is horizontal with respect to first main surface 1 and vertical with respect to second direction 102. First direction 101 is <11-20> direction, for example.

First main surface 1 is an epitaxial layer formation surface, for example. In other words, a silicon carbide epitaxial layer (not shown) is disposed on first main surface 1. Second main surface 2 is a drain electrode formation surface, for example. In other words, a drain electrode (not shown) of an MOSFET (Metal Oxide Semiconductor Field Effect Transistor) is disposed on second main surface 2.

As illustrated in FIG. 2, silicon carbide substrate 10 includes a plurality of screw dislocations 13, pits 11, and a silicon carbide region 22. The plurality of screw dislocations 13 include first screw dislocations 6 that continues to pits 11, and second screw dislocations 7 that does not continue to pits 11. In other words, pits 11 are attributed to first screw dislocations 6. Pits 11 open in first main surface 1, and not in second main surface 2. First screw dislocations 6 continue to second main surface 2. Second screw dislocations 7 continue to both of first main surface 1 and second main surface 2. In other words, second screw dislocations 7 penetrate silicon carbide region 22 from first main surface 1 to second main surface 2.

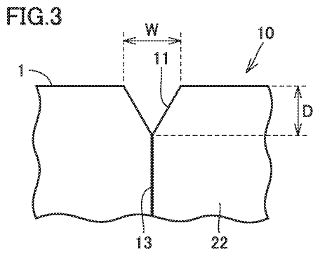

FIG. 3 is a schematic enlarged view of a region III in FIG. 2. As illustrated in FIG. 3, widths (diameters) of pits 11 decrease from first main surface 1 to second main surface 2. Pits 11 may be in an approximate conical shape, for example. Pits 11 are in an approximate circular shape viewed in a vertical direction with respect to first main surface 1. A maximum diameter (first diameter W) of pits 11 in a direction parallel to first main surface 1 is equal to or greater than 1 μm and equal to or smaller than 10 μm. First diameter W may be equal to or greater than 2 μm, or may be equal to or greater than 3 μm. A maximum depth (first depth D) of pits 11 in a direction vertical to first main surface 1 is equal to or greater than 3 nm and equal to or smaller than 1 μm.

As illustrated in FIG. 2, a number of screw dislocations 13 is greater than a number of pits 11. Specifically, when screw dislocations 13 and pits 11 are observed on first main surface 1, a ratio obtained by dividing the number of pits 11 by the number of screw dislocations 13 is equal to or smaller than 1%. The ratio obtained by dividing the number of pits 11 by the number of screw dislocations 13 may be equal to or smaller than 0.5%, may be equal to or smaller than 0.4%, or may be equal to or smaller than 0.3%. A lower limit of the ratio obtained by dividing the number of pits 11 by the number of screw dislocations 13 is not particularly limited, but may be equal to or greater than 0.01%, or may be equal to or greater than 0.1%, for example.

A surface density of screw dislocations 13 on first main surface 1 is equal to or greater than 100 cm⁻² and equal to or smaller than 5000 cm⁻², for example. A lower limit of the surface density of screw dislocations 13 on first main surface 1 is not particularly limited, but may be equal to or greater than 200 cm⁻², or may be equal to or greater than 500 cm⁻², for example. An upper limit of the surface density of screw dislocations 13 on first main surface 1 is not particularly limited, but may be equal to or smaller than 4500 cm⁻², or may be equal to or smaller than 4000 cm⁻², for example.

(Method for Measuring Screw Dislocations)

The number of screw dislocations 13 can be measured using an X-ray topography method, for example. A measurement device is XRTmicron manufactured by Rigaku Corporation, for example. Specifically, the number of screw dislocations 13 may be measured based on an X-ray topographic image of first main surface 1 of silicon carbide substrate 10. The X-ray topographic image is taken by (0008) reflection. A Cu target is used as an X-ray source at the time of measurement. A pixel size of the X-ray camera is 5.4 μm.

(Method for Measuring Pits)

The number of pits 11 may be measured using a defect inspection apparatus having a confocal differential interference microscope, for example. The defect inspection apparatus is “SICA6X” of WASAVI series manufactured by Lasertec Corporation, for example. A magnification of an objective lens is 10 times, for example. Specifically, first main surface 1 of silicon carbide substrate 10 is irradiated with a light of wavelength 546 nm from a light source such as a mercury xenon lamp, and reflected light of this light is observed by a light receiving element such as a CCD (Charge-Coupled Device), for example.

A difference between brightness of a certain pixel in the observed image and brightness of pixels around the certain pixel is quantified. A threshold of detection sensitivity of the defect inspection apparatus is determined using a standard sample. By using the defect inspection apparatus, the diameter of pits 11 formed in the sample to be measured can be quantitatively evaluated. By observing first main surface 1 of silicon carbide substrate 10, pits 11 having a maximum diameter (first diameter W) of equal to or greater than 1 μm and equal to or smaller than 10 μm is detected.

First main surface 1 has a surface roughness equal to or smaller than 0.15 nm. The surface roughness of first main surface 1 may be equal to or smaller than 0.13 nm, or may be equal to or smaller than 0.11 nm, for example. A lower limit of the surface roughness of first main surface 1 is not particularly limited, but may be equal to or greater than 0.01 nm, for example. The surface roughness of first main surface 1 is defined as an arithmetic average roughness (Sa). Arithmetic average roughness (Sa) is a parameter obtained by expanding a two-dimensional arithmetic average roughness (Ra) into three dimensions.

(Method for Measuring Surface Roughness)

Arithmetic average roughness (Sa) may be measured by a white light interferometric microscope, for example. Specifically, first main surface 1 of silicon carbide substrate 10 is observed by the white light interferometric microscope. As the white light interferometric microscope, BW-D507 manufactured by Nikon Corporation may be used, for example. A range of measurement of arithmetic average roughness (Sa) is a square region of 255 μm×255 μm, for example. A center of a diagonal line of the square region is a center of first main surface 1, for example. A center of first main surface 1 is a center of a circle including arcuate portion 4, for example. One side of the square region is parallel to first direction 101.

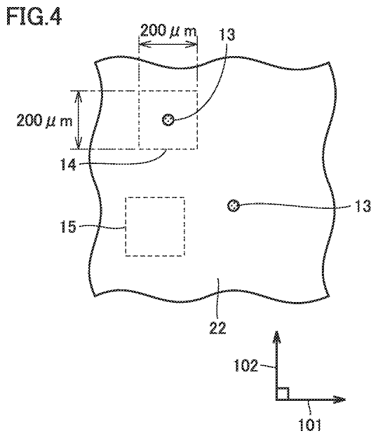

FIG. 4 is a schematic enlarged view of a region IV in FIG. 1. As illustrated in FIG. 4, first main surface 1 includes first square region 14 and second square region 15. First square region 14 includes screw dislocations 13. Silicon carbide region 22 is disposed around screw dislocations 13. As illustrated in FIG. 4, first square region 14 includes screw dislocations 13 and silicon carbide region 22. A length of one side of first square region 14 is 200 μm. That is, first square region 14 is a square region of 200 μm×200 μm. Screw dislocation 13 is positioned in the center of the square. One side of first square region 14 is parallel to first direction 101.

As illustrated in FIG. 4, second square region 15 includes no screw dislocation 13. Second square region 15 includes silicon carbide region 22. A length of one side of second square region 15 is 200 μm. That is, second square region 15 is a square region of 200 μm×200 μm. One side of second square region 15 is parallel to first direction 101. Each of first square region 14 and second square region 15 has a Raman characteristic described later.

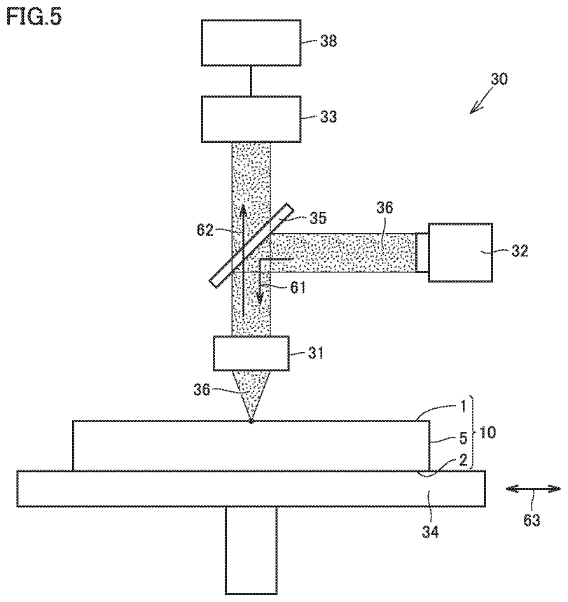

First, a configuration of a Raman spectrometer for measuring a Raman spectrum will be described. FIG. 5 is a schematic view illustrating the configuration of the Raman spectrometer.

As illustrated in FIG. 5, a Raman spectrometer 30 mainly includes, for example, a light source 32, an objective lens 31, a spectrometer 33, a stage 34, a beam splitter 35, and a detector 38. As Raman spectrometer 30, LabRAM HR-800 manufactured by HORIBA Jobin Yvon GmbH may be used, for example. Light source 32 is a YAG (Yttrium Aluminum Garnet) laser, for example. An excitation wavelength of light source 32 is 532 nm, for example. An irradiation intensity of the laser is 10 mW, for example. The measurement method is backscattering measurement, for example. A magnification of objective lens 31 is 100 times. A diameter of a measurement region is 1 μm, for example. An irradiation time of the laser is 20 seconds, for example. A number of times of integration is five, for example. Grating is 2400 gr/mm.

Next, the method for measuring a Raman spectrum will be described.

First, incident light 36 is radiated from a YAG laser of light source 32. As illustrated by an arrow 61 in FIG. 5, incident light 36 is reflected on beam splitter 35 and directed toward first main surface 1 of silicon carbide substrate 10. Raman spectrometer 30 employs a confocal optical system, for example. In the confocal optical system, a confocal aperture (not shown) having a circular opening is arranged at a position conjugate with a focal point of objective lens 31. As a result, it is possible to detect light only at a focused position.

As illustrated by an arrow 62 in FIG. 5, Raman scattered light scattered by silicon carbide substrate 10 passes through beam splitter 35 and is introduced into spectrometer 33. In spectrometer 33, the Raman scattered light is resolved for each wave number. The Raman scattered light resolved for each wave number is detected by detector 38. As a result, it is possible to obtain a Raman spectrum taking the wave number as a horizontal axis, and an intensity of the Raman scattered light as a vertical axis. Stage 34 is able to move in a direction (a direction of an arrow 63) parallel to first main surface 1 of silicon carbide substrate 10.

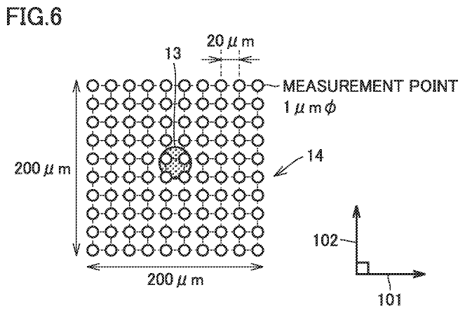

FIG. 6 is a schematic view illustrating measurement points of a Raman spectrum in first square region 14. As illustrated in FIG. 6, Raman spectra are measured at a plurality of measurement points in first square region 14. Measurement points of Raman spectrum are circled regions having a diameter of about 1 μm and indicated by white circles. For example, first, Raman spectrum is measured at a position at a left down corner of first square region 14 (first position). Next, stage 34 is moved to the direction parallel to first main surface 1, and the position of the focal point of incident light 36 is adjusted upward, for example. As a result, a Raman spectrum at a second position that is away from the first position in second direction 102 by 20 μm is measured. As described above, by moving stage 34 along the direction of arrow 63, the Raman spectrum is measured at the plurality of measurement points of first square region 14. Pitch of the measurement positions is 20 μm, for example. A number of measurement positions is 10 (in first direction 101)×10 (in second direction 102)=100, for example.

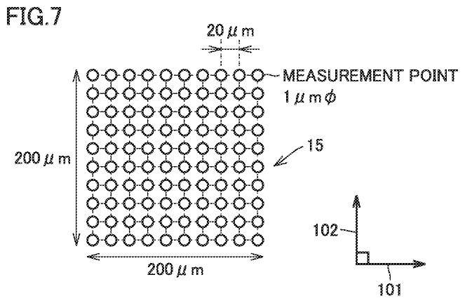

FIG. 7 is a schematic view illustrating measurement points of a Raman spectrum in second square region 15. As illustrated in FIG. 7, Raman spectra are measured at a plurality of measurement points in second square region 15. Measurement points of Raman spectrum are circled regions having a diameter of about 1 μm and indicated by white circles. For example, first, Raman spectrum is measured at a position at a left down corner of second square region 15 (third position). Next, stage 34 is moved to the direction parallel to first main surface 1, and the position of the focal point of incident light 36 is adjusted upward, for example. As a result, a Raman spectrum at a fourth position that is away from the third position in second direction 102 by 20 μm is measured. As described above, by moving stage 34 along the direction of arrow 63, the Raman spectrum is measured at the plurality of measurement points of second square region 15. Pitch of the measurement positions is 20 μm, for example. A number of measurement positions is 10 (in first direction 101)×10 (in second direction 102)=100, for example.

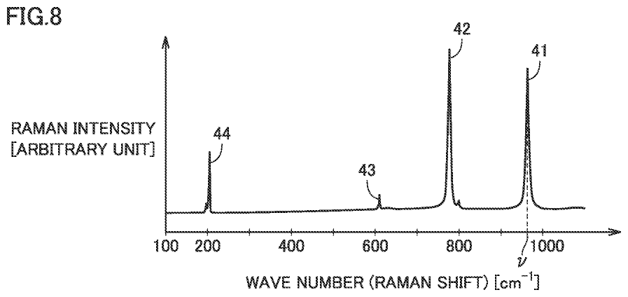

FIG. 8 is a schematic view illustrating one example of the Raman spectrum of silicon carbide substrate 10. A horizontal axis in FIG. 8 represents a wave number (Raman shift). A vertical axis in FIG. 8 represents an intensity of Raman scattered light (Raman intensity). A wavelength of excitation light of light source 32 is 514.5 nm. A Raman shift is a difference between the wavelength of the excitation light and a wave number of the Raman scattered light of an object to be measured. When the object to be measured is 4H polytype silicon carbide, four peaks are mainly observed in the Raman spectrum. A first peak 41 is Raman scattered light resulting from a folding mode of longitudinal wave optical (LO) branch. First peak 41 appears around 964 cm⁻¹, for example. A second peak 42 is Raman scattered light resulting from a folding mode of transverse wave optical (TO) branch. Second peak 42 appears around 776 cm⁻¹, for example. A third peak 43 is Raman scattered light resulting from a folding mode of longitudinal wave acoustic (LA) branch. Third peak 43 appears around 610 cm⁻¹, for example. A fourth peak 44 is Raman scattered light resulting from a folding mode of transverse wave acoustic (TA) branch. Fourth peak 44 appears around 196 cm⁻¹, for example.

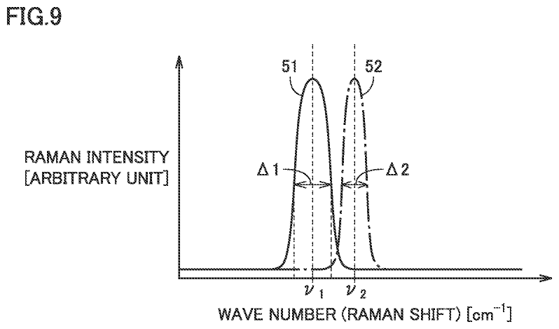

FIG. 9 is a schematic view illustrating the Raman spectrum measured in first square region 14 and the Raman spectrum measured in second square region 15. A Raman spectrum (first Raman spectrum 51) indicated by a solid line in FIG. 9 indicates a Raman spectrum of silicon carbide measured in first square region 14. A wave number v₁ of a peak corresponding to the folding mode of the longitudinal optical branch is obtained using first Raman spectrum 51. The peak corresponding to the folding mode of the longitudinal optical branch is a peak of a Raman spectrum resulted from the folding mode of the longitudinal optical branch. Similarly, a full width at half maximum Δ1 of the peak corresponding to the folding mode of the longitudinal optical branch is obtained using first Raman spectrum 51.

Specifically, full width at half maximum Δ1 is a full width at half maximum (FWHM). Wave number v₁ and full width at half maximum Δ1 is obtained at each of 100 measurement positions in first square region 14. In first square region 14, an average value of wave numbers v₁ is the first wave number. In first square region 14, an average value of full width at half maximum Δ1 is the first full width at half maximum.

A Raman profile (second Raman spectrum 52) indicated by an alternate long and short dash line in FIG. 9 indicates a Raman spectrum measured in second square region 15. A wave number v₂ of the peak corresponding to the folding mode of the longitudinal optical branch is obtained using second Raman spectrum 52. Similarly, a full width at half maximum Δ2 of the peak corresponding to the folding mode of the longitudinal optical branch is obtained using second Raman spectrum 52. Specifically, full width at half maximum Δ2 is a full width at half maximum (FWHM). Wave number v₂ and full width at half maximum Δ2 is obtained at each of 100 measurement positions in second square region 15. In second square region 15, an average value of wave number v₂ is the second wave number. In second square region 15, an average value of full width at half maximum Δ2 is the second full width at half maximum.

In silicon carbide substrate 10 according to the present embodiment, the absolute value of the difference between the first wave number and the second wave number is 0.2 cm⁻¹ or less, and the absolute value of the difference between the first full width at half maximum and the second full width at half maximum is 0.25 cm⁻¹ or less. The absolute value of the difference between the first wave number and the second wave number may be 0.18 cm⁻¹ or less, or 0.16 cm⁻¹ or less. A lower limit of the absolute value of the difference between the first wave number and the second wave number is not particularly limited, but may be equal to or greater than, for example, 0.14 cm⁻¹.

The absolute value of the difference between the first full width at half maximum and the second full width at half maximum may be 0.23 cm⁻¹ or less, or 0.21 cm⁻¹ or less. A lower limit of the absolute value of the difference between the first full width at half maximum and the second full width at half maximum is not particularly limited, but may be, for example, 0.20 cm⁻¹ or more. The wave number of the peak corresponding to the folding mode of the longitudinal optical branch and the full width at half maximum of the peak change depending on a stress in the measurement region. When polishing damage is small, the absolute value of the difference between the first wave number and the second wave number and the absolute value of the difference between the first full width at half maximum and the second full width at half maximum are small. In other words, by defining the absolute value of the difference between the first wave number and the second wave number and the absolute value of the difference between the first full width at half maximum and the second full width at half maximum, a degree of polishing damage can be quantified.

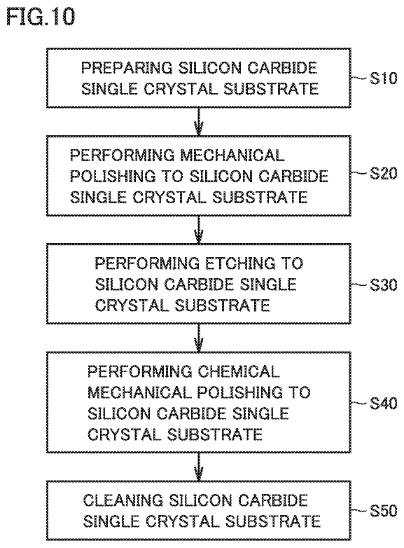

Next, the method for manufacturing silicon carbide substrate 10 according to the present embodiment will be described. FIG. 10 is a flow chart schematically illustrating a method for manufacturing silicon carbide substrate 10 according to the present embodiment. As shown in FIG. 10, the method for manufacturing silicon carbide substrate 10 according to the present embodiment mainly includes a step of preparing silicon carbide single crystal substrate 100 (S10: FIG. 10), a step of mechanically polishing silicon carbide single crystal substrate 100 (S20: FIG. 10), a step of etching silicon carbide single crystal substrate 100 (S30: FIG. 10), a step of chemically mechanically polishing silicon carbide single crystal substrate 100 (S40: FIG. 10), and a step of cleaning silicon carbide single crystal substrate 100 (S50: FIG. 10).

First, the step of preparing silicon carbide single crystal substrate 100 (S10: FIG. 10) is performed. Specifically, for example, an ingot made of 4H polytype silicon carbide single crystal is provided by a sublimation method. After the ingot is shaped, the ingot is sliced by a wire saw device. As a result, silicon carbide single crystal substrate 100 is cut out from the ingot.

Silicon carbide single crystal substrate 100 is made of 4H polytype hexagonal silicon carbide. Silicon carbide single crystal substrate 100 includes first main surface 1 and second main surface 2 opposite to first main surface 1. First main surface 1 is, for example, a surface turned off by 4° or less in a <11-20> direction with respect to a {0001} plane. Specifically, first main surface 1 is, for example, a surface turned off by an angle of about 4° or less with respect to a (0001) plane. Second main surface 2 is, for example, a surface turned off by an angle of about 4° or less with respect to a (000-1) plane.

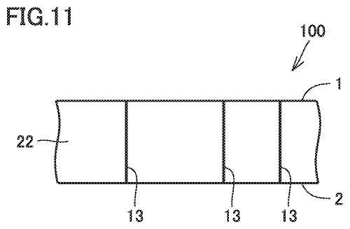

As illustrated in FIG. 11, silicon carbide substrate 10 has first main surface 1, second main surface 2, a plurality of screw dislocations 13, and silicon carbide region 22. The plurality of screw dislocations 13 are connected to both of first main surface 1 and second main surface 2. In other words, the plurality of screw dislocations 13 penetrate silicon carbide region 22 from first main surface 1 to second main surface 2. As described above, silicon carbide single crystal substrate 100 having first main surface 1 and second main surface 2 on an opposite side of first main surface 1 is prepared.

Next, the step of mechanically polishing silicon carbide single crystal substrate 100 (S20: FIG. 10) is performed. Specifically, first main surface 1 is disposed so as to face a surface plate (not shown). Next, a slurry is introduced between first main surface 1 and the surface plate. The slurry contains, for example, diamond abrasive grains. The diamond abrasive grains have a diameter of, for example, 1 μm or more and 3 μm or less. A load is applied to first main surface 1 by the surface plate. As described above, mechanical polishing is performed to silicon carbide single crystal substrate 100 on first main surface 1.

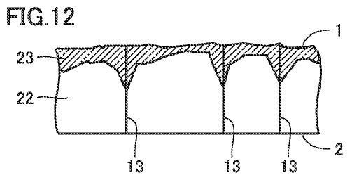

As illustrated in FIG. 12, in the mechanical polishing to silicon carbide single crystal substrate 100, a damage layer 23 is provided on first main surface 1. In a portion where screw dislocation 13 is present, damage layer 23 is easily formed as compared with a normal crystal portion where screw dislocation 13 is not present. Therefore, a thickness of damage layer 23 in the portion along screw dislocation 13 is larger than thickness of damage layer 23 along the region where screw dislocation 13 does not exist. In other words, damage layer 23 is formed so as to erode silicon carbide region 22 along the extending direction of the screw dislocations 13.

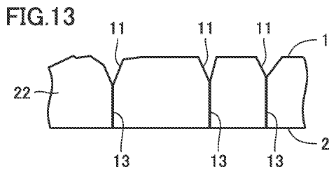

Next, the step of etching silicon carbide single crystal substrate 100 (S30: FIG. 10) is performed. As illustrated in FIG. 13, in the step of etching silicon carbide single crystal substrate 100, damage layer 23 provided in the mechanical polishing step is removed. After damage layer 23 is removed from first main surface 1, pits 11 are formed on first main surface 1. Pits 11 are continuous with screw dislocations 13.

Silicon carbide single crystal substrate 100 may be etched in a gas phase or a liquid phase. Preferably, the step of etching silicon carbide single crystal substrate 100 is performed by causing damage layer 23 to be immersed in an etching solution. The etching solution contains potassium hydroxide (KOH) and potassium permanganate (KMnO₄), and pure water, for example. A volume ratio of the etching solution is, for example, KOH:KMnO₄:pure water=5 to 15:1 to 3:30 to 40.

The step of etching silicon carbide single crystal substrate 100 is performed under a temperature equal to or lower than 400° C., for example. The step of etching silicon carbide single crystal substrate 100 may be performed at, for example, 350° C. or lower, or 300° C. or lower. Specifically, the temperature of the etching solution is equal to or higher than 60° C. and equal to or lower than 70° C., for example. An etching amount is, for example, about 1 μm or more and 5 μm or less. The step of etching silicon carbide single crystal substrate 100 is performed after the step of mechanically polishing silicon carbide single crystal substrate 100.

Next, the step of chemically mechanically polishing silicon carbide single crystal substrate 100 (S40: FIG. 10) is performed. First, a condition of chemical mechanical polishing (CMP) is determined. The condition of CMP is a condition in which mechanical elements and chemical elements are balanced. Specifically, a polishing rate of silicon carbide single crystal substrate 100 and surface roughness (Sa) of first main surface 1 of silicon carbide single crystal substrate 100 are measured while fixing the size of the abrasive grains of CMP and changing the concentration of the oxidant.

Specifically, CMP is performed to silicon carbide single crystal substrate 100 using abrasive grains and an oxidant on first main surface 1. For example, silicon carbide single crystal substrate 100 is held by a polishing head (not shown) such that first main surface 1 faces the surface plate (not shown). The abrasive grains are colloidal silica, for example. An average grain size of the abrasive grains is 20 nm. A processing surface pressure is, for example, 400 g/cm². A rotation number of the surface plate is, for example, 60 rpm. A rotation number of the polishing head is 60 rpm. The oxidant is, for example, an aluminum nitrate aqueous solution. An oxidant concentration is, for example, 5%, 10%, 15%, 20%, and 25%. The oxidant concentration is a value obtained by dividing a mass of the solute (aluminum nitrate) by a total mass of the solute (aluminum nitrate) and the solvent (water).

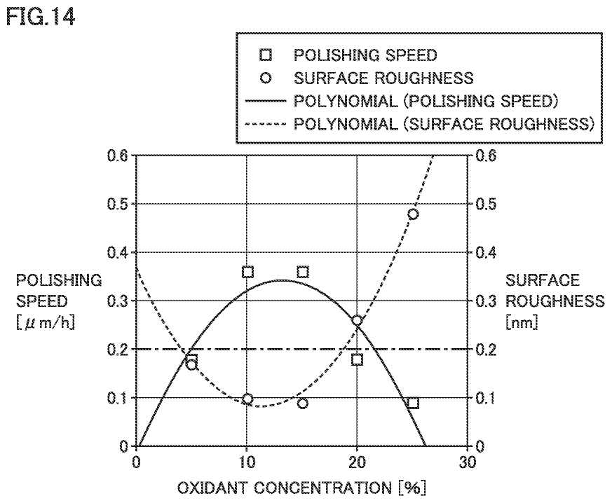

FIG. 14 is a chart showing a relationship between the polishing speed and the oxidant concentration, and a relationship between the surface roughness and the oxidant concentration. The vertical axis on the left side is the polishing speed. The right vertical axis is the surface roughness of first main surface 1. The horizontal axis is the oxidant concentration.

In FIG. 14, white squares are data of the polishing speed. A solid line is a line obtained by approximating the value of the polishing speed with a quadratic curve (polynomial). The quadratic curve is a curve expressed by a quadratic equation. The relationship between the polishing speed and the oxidant concentration is approximated by a downwardly convex quadratic curve. In FIG. 14, white circles are data of surface roughness (Sa) of first main surface 1. A broken line is a line obtained by approximating the value of the surface roughness of first main surface 1 with a quadratic curve (first quadratic curve). The relationship between the surface roughness of first main surface 1 and the oxidant concentration is approximated by an upwardly convex quadratic curve.

The concentration of the oxidant is determined so as to be within a range in which the surface roughness is 1.5 times or less of the local minimum value of the first quadratic curve. As illustrated in FIG. 14, the local minimum value of the first quadratic curve indicated by a broken line is 0.09 nm. 1.5 times of the local minimum value is 0.135 nm. Therefore, the concentration of the oxidant is determined within a range in which the surface roughness is 0.135 nm or less. Specifically, the concentration of the oxidant is determined in a range of, for example, 8% or more and 16% or less. Preferably, the concentration of the oxidant is determined so as to be within a range in which the surface roughness is 1.3 times or less the local minimum value of the first quadratic curve.

The concentration of the oxidant is determined in a range in which the polishing speed of silicon carbide single crystal substrate 100 is 0.2 μm/hour or more. As shown in FIG. 14, the concentration of the oxidant at which the polishing speed of silicon carbide single crystal substrate 100 is 0.2 μm/hour or more is, for example, in a range of 5% or more and 22% or less. That is, the concentration of the oxidant that is within the range in which the surface roughness is 1.5 times or less of the local minimum value of the first quadratic curve and the polishing speed of silicon carbide single crystal substrate 100 is 0.2 μm/hour or more is, for example, in the range of 8% or more and 16% or less.

As illustrated in FIG. 14, the local minimum value of the first quadratic curve indicated by a broken line is equal to or smaller than 0.15 nm, for example. The local minimum value of the first quadratic curve indicated by the broken line may be equal to or smaller than 0.13 nm, or may be equal to or smaller than 0.11 nm, for example.

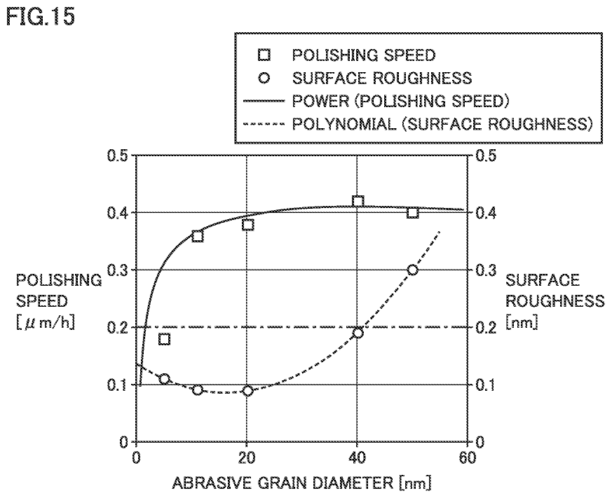

FIG. 15 is a chart showing a relationship between the polishing speed and an abrasive grain diameter, and a relationship between the surface roughness and the abrasive grain diameter. The vertical axis on the left side is the polishing speed. The right vertical axis is surface roughness (Sa) of first main surface 1. The horizontal axis is the abrasive grain diameter (abrasive grain diameter).

In FIG. 15, white squares are data of the polishing speed. The solid line is a line obtained by approximating the value of the polishing speed to a power. When the abrasive grain diameter is less than 6 nm, the polishing speed rapidly decreases. When the abrasive grain diameter is 6 nm or more, the polishing speed does not change much. In FIG. 15, white circles are data of the surface roughness of first main surface 1. A broken line is a line obtained by approximating the value of the surface roughness of first main surface 1 with a quadratic curve (second quadratic curve). The relationship between the surface roughness of first main surface 1 and the abrasive grain diameter is approximated by a downwardly convex quadratic curve.

The diameter of the abrasive grains may be determined so as to be within a range in which the surface roughness is 1.5 times or less of the local minimum value of the second quadratic curve. As illustrated in FIG. 15, the local minimum value of the second quadratic curve indicated by a broken line is 0.09 nm. 1.5 times of the local minimum value is 0.135 nm. Therefore, the diameter of the abrasive grains is determined within a range in which the surface roughness is 0.135 nm or less. Specifically, the diameter of the abrasive grains is determined in a range of, for example, 30 nm or less. Preferably, the diameter of the abrasive grains is determined so as to be within a range of surface roughness of 1.3 times or less of the local minimum value of the second quadratic curve.

As described above, the oxidant concentration and the diameter of the abrasive grains are determined. The oxidant concentration is, for example, 10%. The diameter of the abrasive grains is, for example, 20 nm. CMP is performed to silicon carbide single crystal substrate 100 on first main surface 1 under the above conditions. The CMP to silicon carbide single crystal substrate 100 is performed after the step of etching silicon carbide single crystal substrate 100.

Next, the step of cleaning silicon carbide single crystal substrate 100 (S50: FIG. 10) is performed. The step of cleaning silicon carbide single crystal substrate 100 includes, for example, a sulfuric acid hydrogen peroxide cleaning step, an ammonia hydrogen peroxide cleaning step, a hydrochloric acid hydrogen peroxide cleaning step, and a hydrofluoric acid cleaning step.

First, the sulfuric acid hydrogen peroxide cleaning step is performed. Sulfuric acid hydrogen peroxide mixture is a solution obtained by mixing sulfuric acid, hydrogen peroxide water, and ultrapure water. As the sulfuric acid, for example, concentrated sulfuric acid having a mass percentage concentration of 96% can be used. As the hydrogen peroxide water, for example, hydrogen peroxide water having a mass percentage concentration of 30% can be used. The same applies to the hydrogen peroxide water used in the subsequent steps. A volume ratio of sulfuric acid, hydrogen peroxide water, and ultrapure water contained in the sulfuric acid hydrogen peroxide mixture is, for example, 10 (sulfuric acid):1 (hydrogen peroxide water):1 (ultrapure water) to 10 (sulfuric acid):3 (hydrogen peroxide water):1 (ultrapure water).

Next, the ammonia hydrogen peroxide cleaning step is performed. Ammonia hydrogen peroxide mixture is a solution obtained by mixing an ammonia aqueous solution, hydrogen peroxide water, and ultrapure water. As the ammonia aqueous solution, for example, an ammonia aqueous solution having a mass percentage concentration of 28% can be used. The volume ratio among the ammonia aqueous solution, the hydrogen peroxide water, and the ultrapure water contained in the ammonia hydrogen peroxide mixture is, for example, 1 (ammonia aqueous solution):1 (hydrogen peroxide water):5 (ultrapure water) to 1 (ammonia aqueous solution):1 (hydrogen peroxide water):10 (ultrapure water).

Next, the hydrochloric acid hydrogen peroxide cleaning step is performed. Hydrochloric acid hydrogen peroxide mixture is a solution in which hydrochloric acid, hydrogen peroxide water, and ultrapure water are mixed. As the hydrochloric acid, for example, concentrated hydrochloric acid having a mass percentage concentration of 98% can be used. The volume ratio of hydrochloric acid, hydrogen peroxide water, and ultrapure water contained in the hydrochloric acid hydrogen peroxide mixture is, for example, 1 (hydrochloric acid):1 (hydrogen peroxide water):5 (ultrapure water) to 1 (hydrochloric acid):1 (hydrogen peroxide water):10 (ultrapure water).

Next, the hydrofluoric acid cleaning step is performed. A concentration of hydrofluoric acid in a mixture of hydrofluoric acid and ultrapure water is, for example, 10% or more and 40% or less. A temperature of hydrofluoric acid is, for example, room temperature. As described above, silicon carbide substrate 10 according to the present embodiment is manufactured (see FIG. 1).

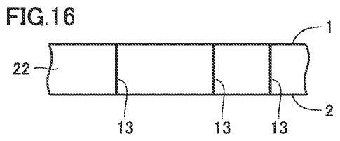

FIG. 16 is a partial schematic cross-sectional view illustrating a configuration of silicon carbide substrate 10 according to the present embodiment. As illustrated in FIG. 16, in silicon carbide substrate 10 according to the present embodiment, there are few pits 11 having a maximum diameter of 1 μm or more and 10 μm or less. Specifically, when screw dislocations 13 and pits 11 are observed on first main surface 1, a ratio obtained by dividing the number of pits 11 by the number of screw dislocations 13 is equal to or smaller than 1%.

Next, functions and effects of silicon carbide substrate 10 according to the present embodiment will be described.

As illustrated in FIG. 12, when mechanical polishing is performed to silicon carbide single crystal substrate 100, damage layer 23 is formed on first main surface 1. Damage layer 23 is a portion in which the crystal structure of silicon carbide collapses and becomes amorphous. In damage layer 23, a stress is higher than that in silicon carbide region 22 other than damage layer 23. After mechanical polishing is performed to silicon carbide single crystal substrate 100, CMP is performed to silicon carbide single crystal substrate 100. In CMP, mechanical elements and chemical elements act.

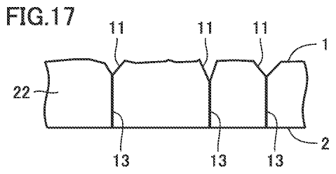

FIG. 17 is a schematic cross-sectional view illustrating a configuration of silicon carbide single crystal substrate 100 after CMP in a case where chemical elements are dominant. A portion of damage layer 23 where screw dislocation 13 is present is likely to be eroded by chemical components of CMP. Therefore, pit 11 is easily formed in a portion where screw dislocation 13 is present (see FIG. 17).

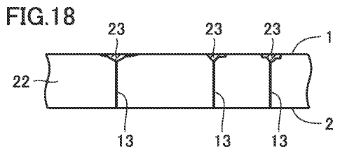

FIG. 18 is a schematic cross-sectional view illustrating a configuration of silicon carbide single crystal substrate 100 after CMP in a case where mechanical elements are dominant. When the mechanical elements are dominant, the chemical elements become relatively weak. Therefore, the portion of damage layer 23 where screw dislocation 13 is present is not eroded much by chemical components of CMP. On the other hand, since the mechanical elements are relatively strong, damage layer 23 remains in a portion where screw dislocation 13 is present. As a result, pits 11 are not easily formed on first main surface 1 (see FIG. 18). First main surface 1 has a substantially flat appearance.

When a silicon carbide layer is formed on first main surface 1 of silicon carbide substrate 10 by epitaxial growth, hydrogen etching to silicon carbide substrate 10 is performed on first main surface 1. Damage layer 23 remaining at a portion where screw dislocation 13 is present is easily removed by hydrogen etching.

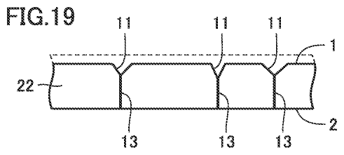

FIG. 19 is a schematic cross-sectional view illustrating the configuration of silicon carbide substrate 10 after hydrogen etching is performed to silicon carbide substrate 10 after CMP in a case where mechanical elements are dominant. As illustrated in FIG. 19, damage layer 23 remaining in a portion where screw dislocation 13 is present is removed by hydrogen etching. As a result, a large number of pits 11 are formed on first main surface 1 of silicon carbide substrate 10. Thereafter, when a silicon carbide epitaxial layer is formed on first main surface 1 by epitaxial growth, a large number of pits 11 remain also on a surface of the silicon carbide epitaxial layer.

Silicon carbide substrate 10 according to the present embodiment is formed using a CMP process in which mechanical elements and chemical elements are balanced. Therefore, in the CMP process, pits 11 are removed without forming damage layer 23. As a result, silicon carbide substrate 10 in which damage layer 23 and pits 11 are suppressed is obtained (see FIG. 16).

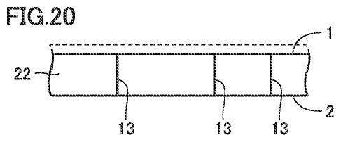

FIG. 20 is a schematic cross-sectional view illustrating the configuration of silicon carbide substrate 10 after hydrogen etching is performed to silicon carbide substrate 10 after CMP in a case where mechanical elements and chemical elements are balanced. As illustrated in FIG. 20, since damage layer 23 does not remain even after hydrogen etching, pit 11 is hardly formed on first main surface 1. That is, even when hydrogen etching to silicon carbide substrate 10 is performed on first main surface 1, formation of pits 11 on first main surface 1 of silicon carbide substrate 10 can be suppressed. Therefore, when the silicon carbide epitaxial layer is formed on first main surface 1 by epitaxial growth, formation of pits 11 on the surface of the silicon carbide epitaxial layer can be suppressed.

### Example

(Sample Preparation)

First, silicon carbide substrate 10 according to samples 1 to 3 was prepared. Silicon carbide substrate 10 according to samples 1 and 2 was used as comparative examples. Silicon carbide substrate 10 according to sample 3 was used as a practical example. To silicon carbide substrate 10 according to sample 3, the step of etching silicon carbide single crystal substrate 100 (S30: FIG. 10) was performed. On the other hand, to the silicon carbide substrates 10 according to samples 1 and 2, the step of etching silicon carbide single crystal substrate 100 (S30: FIG. 10) was not performed.

For silicon carbide substrate 10 according to sample 1, the dominant elements in the step of chemically mechanically polishing silicon carbide single crystal substrate 100 (S40: FIG. 10) were mechanical elements. For silicon carbide substrate 10 according to sample 2, the dominant elements in the step of chemically mechanically polishing silicon carbide single crystal substrate 100 (S40: FIG. 10) were chemical elements. For silicon carbide substrate 10 according to sample 3, the mechanical element and the chemical element were set to the same level as the dominant element in the step of chemically mechanically polishing silicon carbide single crystal substrate 100 (S40: FIG. 10). In silicon carbide substrate 10 according to each of samples 1 to 3, screw dislocation densities were 390 dislocations/cm², 420 dislocations/cm², and 350 dislocations/cm², respectively.

(Evaluation Method)

Using the X-ray topography method, density of screw dislocations 13 on first main surface 1 of silicon carbide substrate 10 according to samples 1 to 3 was measured. Using a defect inspection apparatus, a density of pits 11 of first main surface 1 of silicon carbide substrate 10 according to samples 1 to 3 was measured. The maximum diameter (diameter) of pits 11 is 1 μm or more and 10 μm or less.

Using a white light interferometric microscope, the surface roughness of first main surface 1 of silicon carbide substrates 10 according to samples 1 to 3 was measured. The surface roughness of first main surface 1 was defined as arithmetic average roughness (Sa). A range of measurement of arithmetic average roughness (Sa) was a square region of 255 μm×255 μm. The center of a diagonal line of the square region was a center of first main surface 1. One side of the square region was parallel to the extending direction of the first flat.

Using Raman spectroscopy, a Raman spectrum of silicon carbide substrate 10 was measured in each of first square region 14 and second square region 15 of first main surface 1 of silicon carbide substrate 10 according to samples 1 to 3. First square region 14 is a region including screw dislocations 13. First square region 14 is a square region of 200 μm×200 μm. A number of measurement points is 100. Second square region 15 is a region including no screw dislocation 13. Second square region 15 is a square region of 200 μm×200 μm. A number of measurement points is 100. The average value of Δv (Ne) and the average value of the full widths at half maximum (FWHM) of the peaks were obtained using the Raman spectrum.

Δv (Ne) is a value obtained by subtracting the wave number of the peak of the Raman spectrum of neon from the wave number of the peak corresponding to the folding mode of the longitudinal optical branch of 4H polytype silicon carbide. The wave number of the peak corresponding to the folding mode of the longitudinal optical branch of silicon carbide was obtained based on the wave number indicating the peak of the Raman spectrum of neon. The full widths at half maximum (FWHM) of the peaks are full widths at half maximum of the peaks corresponding to the folding mode of the longitudinal optical branch of 4H polytype silicon carbide.

Next, a silicon carbide epitaxial layer was formed on first main surface 1 by epitaxial growth. The density of pits 11 on the surface of the silicon carbide epitaxial layer was measured using a defect measuring apparatus. A maximum diameter of pits 11 is 1 μm or more and 10 μm or less.

(Evaluation Results)

TABLE 1

| | | | | Sample 1 | Sample 2 | Sample 3 |
|---|---|---|---|---|---|---|
| Etching step | | | | No | No | Yes |
| Chemical | Dominant elements | | | Mechanical | Chemical | Balanced |
| mechanical | | | | element | element | |
| polishing | | | | | | |
| Crystals | Screw dislocation density | | | 390 crystals/cm² | 420 crystals/cm² | 350 crystals/cm² |
| Silicon carbide | Density of pits having diameter from 1 μm | | | 12 pits/cm² | 0.7 pits/cm² | 1.6 pits/cm² |
| substrate | to 10 μm | | | (2161 pits/6 | (127 pits/6 | (285 pits/6 |
| | | | | inches) | inches) | inches) |
| | Generation ratio of pits having diameter | | | 3.0% | 0.2% | 0.4% |
| | from 1 μm to 10 μm with respect to screw | | | | | |
| | dislocations | | | | | |
| | Surface roughness (Sa) [nm] 250 μm × | | | 0.26 | 0.19 | 0.09 |
| | 250 μm | | | | | |
| | Raman | Δν (Ne) | First square | −44.05 | −44.25 | −44.33 |
| | spectrum | [cm⁻¹] | region-(1) | | | |
| | | | including screw | | | |
| | | | dislocations | | | |
| | | | Second square | −44.21 | −44.48 | −44.49 |
| | | | region-(2) | | | |
| | | | including no | | | |
| | | | screw dislocation | | | |
| | | | Difference | 0.16 | 0.23 | 0.16 |
| | | | between (1) and | | | |
| | | | (2) | | | |
| | | Full | First square | 2.62 | 2.74 | 2.58 |
| | | width at | region-(3) | | | |
| | | half | including screw | | | |
| | | maximum | dislocations | | | |
| | | [cm⁻¹] | Second square | 2.33 | 2.28 | 2.35 |
| | | | region-(4) | | | |
| | | | including no | | | |
| | | | screw dislocation | | | |
| | | | Difference | 0.29 | 0.46 | 0.23 |
| | | | between (3) and | | | |
| | | | (4) | | | |

| | | | | |
|---|---|---|---|---|
| Surface after | Density of pits having diameter from 1 μm | 375 pits/cm² | 364 pits/cm² | 2.5 pits/cm² |
| epitaxial growth | to 10 μm | (66302 pits/6 | (64338 pits/6 | (445 pits/6 |
| | | inches) | inches) | inches) |

As shown in Table 1, densities of pits 11 on first main surface 1 of silicon carbide substrates 10 according to samples 1 to 3 were 12 pits/cm², 0.7 pits/cm², and 1.6 pits/cm², respectively. Values respectively obtained by dividing the densities of pits 11 by densities of screw dislocations 13 on first main surfaces 1 of silicon carbide substrates 10 according to samples 1 to 3 were 3.0%, 0.2%, and 0.4%, respectively. Surface roughness (Sa) on first main surfaces 1 of silicon carbide substrates 10 according to samples 1 to 3 were 0.26 nm, 0.19 nm, and 0.09 nm, respectively.

In first square regions 14 of first main surfaces 1 of silicon carbide substrates 10 according to samples 1 to 3, Δv(Ne) took values of −44.05 cm⁻¹, −44.25 cm⁻¹, and −44.33 cm⁻¹, respectively. In second square region 15 of first main surface 1 of silicon carbide substrate 10 according to samples 1 to 3, Δv(Ne) took values of −44.21 cm⁻¹, −44.48 cm⁻¹, and −44.49 cm⁻¹, respectively. Differences between Δv(Ne) in first square regions 14 and Δv(Ne) in second square regions 15 of silicon carbide substrates 10 according to samples 1 to 3 were 0.16 cm⁻¹, 0.23 cm⁻¹, and 0.16 cm⁻¹, respectively.

Full widths at half maximum of peaks in first square regions 14 of first main surfaces 1 of silicon carbide substrates 10 according to samples 1 to 3 were 2.62 cm⁻¹, 2.74 cm⁻¹, and 2.58 cm⁻¹, respectively. In second square regions 15 of first main surfaces 1 of silicon carbide substrates 10 according to samples 1 to 3, Δv(Ne) took values of 2.33 cm⁻¹, 2.28 cm⁻¹, and 2.35 cm⁻¹, respectively. Differences between the full widths at half maximum in first square regions 14 and the full widths at half maximum in second square regions 15 of silicon carbide substrates 10 according to samples 1 to 3 were 0.29 cm⁻¹, 0.46 cm⁻¹, and 0.23 cm⁻¹, respectively.

As shown in Table 1, densities of pits 11 on surfaces of silicon carbide epitaxial layers provided by epitaxial growth on first main surfaces 1 of silicon carbide substrates 10 according to samples 1 to 3 were 375 pits/cm², 364 pits/cm², and 2.5 pits/cm², respectively. Based on the above results, it has been confirmed that formation of pits 11 after the epitaxial growth may be suppressed on silicon carbide substrate 10 according to sample 3, as compared to silicon carbide substrates 10 according to samples 1 and 2.

The embodiments and the examples disclosed herein should be considered to be illustrative in all respects and not restrictive. The scope of the present invention is defined by the claims, instead of the descriptions stated above, and it is intended that meanings equivalent to the claims and all modifications within the scope are included.

### REFERENCE SIGNS LIST

1: first main surface, 2: second main surface, 3: first flat, 4: arcuate portion, 5: outer peripheral surface, 6: first screw dislocation, 7: second screw dislocation, 10: silicon carbide substrate, 11: pit, 13: screw dislocation, 14: first square region, 15: second square region, 22: silicon carbide region, 23: damage layer, 30: Raman pectrometer, 31: objective lens, 32: light source, 33: spectrometer, 34: stage, 35: beam splitter, 36: incident light, 38: detector, 41: first peak, 42: second peak, 43: third peak, 44: fourth peak, 51: first Raman spectrum, 52: second Raman spectrum, 61, 62, 63: arrows, 100: silicon carbide single crystal substrate, 101: first direction, 102: second direction, A: maximum diameter, D: first depth, W: first diameter

1. A silicon carbide substrate comprising: a first main surface; and a second main surface on an opposite side of the first main surface, wherein
the silicon carbide substrate includes screw dislocations and pits having a maximum diameter equal to or greater than 1 μm and equal to or smaller than 10 μm in a direction parallel to the first main surface,
when the screw dislocations and the pits are observed on the first main surface, a ratio obtained by dividing a number of the pits by a number of the screw dislocations is equal to or smaller than 1%,
the first main surface has a surface roughness equal to or smaller than 0.15 nm, and
assuming that in a first square region including the screw dislocations and having a side length of 200 μm, an average value of wave numbers indicating peaks corresponding to a folding mode of a longitudinal optical branch of a Raman spectrum of silicon carbide is set as a first wave number,
that in a second square region including no screw dislocation and having a side length of 200 μm, an average value of wave numbers indicating peaks corresponding to a folding mode of a longitudinal optical branch of a Raman spectrum of silicon carbide is set as a second wave number,
that in the first square region, an average value of full widths at half maximum of the peaks corresponding to the folding mode of the longitudinal optical branch of the Raman spectrum of silicon carbide is set as a first full width at half maximum width, and
that in the second square region, an average value of full widths at half maximum of the peaks corresponding to the folding mode of the longitudinal optical branch of the Raman spectrum of silicon carbide is set as a second full width at half maximum,
an absolute value of a difference between the first wave number and the second wave number is equal to or smaller than 0.2 cm⁻¹, and an absolute value of a difference between the first full width at half maximum and the second full width at half maximum is equal to or smaller than 0.25 cm⁻¹.

2. The silicon carbide substrate according to claim 1, wherein
the ratio obtained by dividing the number of the pits by the number of the screw dislocations is equal to or smaller than 0.5%.

3. The silicon carbide substrate according to claim 1, wherein
the ratio obtained by dividing the number of the pits by the number of the screw dislocations is equal to or smaller than 0.4%.

4. The silicon carbide substrate according to claim 1, wherein
the surface roughness of the first main surface is equal to or smaller than 0.1 nm.

5. The silicon carbide substrate according to claim 1, wherein
a diameter of the first main surface is equal to or greater than 150 mm.

6. The silicon carbide substrate according to claim 1, wherein
a surface density of the screw dislocations on the first main surface is equal to or greater than 100 cm⁻² and equal to or smaller than 5000 cm⁻².

7. A method for manufacturing a silicon carbide substrate, the method comprising:
preparing a silicon carbide single crystal substrate having: a first main surface and a second main surface on an opposite side of the first main surface;
performing mechanical polishing to the silicon carbide single crystal substrate on the first main surface;
performing etching to the silicon carbide single crystal substrate after the mechanical polishing to the silicon carbide single crystal substrate; and
performing chemical mechanical polishing to the silicon carbide single crystal substrate using abrasive grains and an oxidant on the first main surface after the etching to the silicon carbide single crystal substrate, wherein
in the mechanical polishing to the silicon carbide single crystal substrate, a damage layer is provided on the first main surface,
in the etching to the silicon carbide single crystal substrate, the damage layer is removed, and
in the chemical mechanical polishing to the silicon carbide single crystal substrate, when, taking a surface roughness of the first main surface as a vertical axis and a concentration of the oxidant as a horizontal axis, a relationship between the surface roughness and the concentration of the oxidant is approximated by a first quadratic curve, the concentration of the oxidant is within a range in which the surface roughness is equal to or smaller by 1.5 times than a local minimum value of the first quadratic curve, and a polishing speed of the silicon carbide single crystal substrate is equal to or higher than 0.2 μm/hour.

8. The method for manufacturing a silicon carbide substrate according to claim 7, wherein
in the chemical mechanical polishing to the silicon carbide single crystal substrate, when, taking the surface roughness of the first main surface as the vertical axis and a diameter of the abrasive grains as the horizontal axis, a relationship between the surface roughness and the diameter of the abrasive grains is approximated by a second quadratic curve, the diameter of the abrasive grains is within a range in which the surface roughness is equal to or smaller by 1.5 times than a local minimum value of the second quadratic curve.

9. The method for manufacturing a silicon carbide substrate according to claim 7, wherein
the etching to the silicon carbide single crystal substrate is performed under a temperature equal to or lower than 400° C.

10. The method for manufacturing a silicon carbide substrate according to claim 7, wherein
the local minimum value of the first quadratic curve is equal to or smaller than 0.15 nm.

11. The method for manufacturing a silicon carbide substrate according to claim 7, wherein
the abrasive grains are colloidal silica.

12. The method for manufacturing a silicon carbide substrate according to claim 7, wherein
the etching to the silicon carbide single crystal substrate is performed by causing the damage layer to be immersed in a solution.

13. The method for manufacturing a silicon carbide substrate according to claim 12, wherein
the solution contains potassium permanganate and potassium hydroxide.
